(19) United States
(12) Patent Application Publication
(10) Pub. No.: US 2026/0352171 A1
(43) Pub. Date: Nov. 5, 2026

(54) MECHANISM FOR CONTROLLING A MULTI-STAGE DIFFERENTIAL POWER AMPLIFIER CIRCUIT

(71) Applicant: Qorvo US, Inc., Greensboro, NC (US)

(72) Inventor: Nadim Khlat, Ceret (FR)

(21) Appl. No.: 19/538,419

(22) Filed: Feb. 12, 2026

Related U.S. Application Data
(60) Provisional application No. 63/767,662, filed on Mar. 6, 2025.

(51) Int. Cl. H03F 3/45; H03F 1/02

(52) U.S. Cl. CPC H03F 3/45475; H03F 1/0233; H03F 2200/105; H03F 2200/451

(57) ABSTRACT

Mechanism for controlling a multi-stage differential power amplifier circuit is disclosed. The multi-stage differential power amplifier circuit includes a driver stage circuit and a pair of differential power amplifiers. The driver stage circuit generates a pair of differential signals from a radio frequency (RF) signal. The pair of differential power amplifiers are each biased by a respective bias voltage to amplify a respective one of the differential signals. Specifically, a first differential power amplifier is so biased to always be active, whereas a second differential power amplifier is so biased to only be active as needed. Herein, a control circuit is configured to detect an instantaneous power level of the RF signal and generate the bias voltages accordingly. As such, the multi-stage differential power amplifier circuit can be self-sufficient in controlling the pair of differential power amplifiers, thus helping to improve transmission efficiency and reduce the need for time-consuming calibration.

### RELATED APPLICATIONS

This application claims the benefit of U.S. provisional patent application Ser. No. 63/767,662, filed on Mar. 6, 2025, the disclosure of which is hereby incorporated herein by reference in its entirety.

### FIELD OF THE DISCLOSURE

The present disclosure is related to a mechanism for controlling a multi-stage differential power amplifier circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) to the power amplifier circuit. Understandably, to achieve the best possible efficiency and performance, the power management circuit must adapt the ET voltage in accordance with a modulation bandwidth of the transmission signal.

### SUMMARY

Embodiments of the disclosure relate to a mechanism for controlling a multi-stage differential power amplifier circuit. The multi-stage differential power amplifier circuit includes a driver stage circuit and a pair of differential power amplifiers. The driver stage circuit generates a pair of differential signals from a radio frequency (RF) signal. The pair of differential power amplifiers are each biased by a respective bias voltage to amplify a respective one of the pair of differential signals. Specifically, a first differential power amplifier is so biased to always be active, whereas a second differential power amplifier is so biased to only be active as needed. In embodiments disclosed herein, a control circuit is configured to detect an instantaneous power level of the RF signal and generate the bias voltages accordingly. As such, the multi-stage differential power amplifier circuit can be self-sufficient in controlling the pair of differential power amplifiers, thus helping to improve transmission efficiency in a wireless device and reduce the need for time-consuming calibration for part-to-part variation.

In one aspect, a multi-stage differential power amplifier circuit is provided. The multi-stage differential power amplifier circuit includes a driver stage circuit. The driver stage circuit is configured to amplify an RF signal and output a first differential signal and a second differential signal each comprising a respective non-inverting signal and a respective inverting signal. The multi-stage differential power amplifier circuit also includes a first differential power amplifier. The first differential power amplifier is biased by a first bias voltage to always be active to amplify the first differential signal based on a supply voltage. The multi-stage differential power amplifier circuit also includes a second differential power amplifier. The second differential power amplifier is biased by a second bias voltage to be activated only when an instantaneous power level of the RF signal is higher than or equal to a first power threshold to amplify the second differential signal based on the supply voltage. The multi-stage differential power amplifier circuit also includes an output stage circuit. The output stage circuit is configured to modulate a load impedance at an output of the first differential power amplifier when the instantaneous power level of the RF signal is higher than the first power threshold but lower than or equal to a second power threshold. The output stage circuit is also configured to constantly keep the load impedance at the output of the first differential power amplifier when the instantaneous power level of the RF signal is lower than or equal to the first power threshold or higher than the second power threshold. The multi-stage differential power amplifier circuit also includes a control circuit. The control circuit is configured to generate the first bias voltage and the second bias voltage based on the instantaneous power level of the RF signal to thereby bias the first differential power amplifier and the second differential power amplifier, respectively.

In another aspect, a wireless device is provided. The wireless device includes a multi-stage differential power amplifier circuit. The multi-stage differential power amplifier circuit includes a driver stage circuit. The driver stage circuit is configured to amplify an RF signal and output a first differential signal and a second differential signal each comprising a respective non-inverting signal and a respective inverting signal. The multi-stage differential power amplifier circuit also includes a first differential power amplifier. The first differential power amplifier is biased by a first bias voltage to always be active to amplify the first differential signal based on a supply voltage. The multi-stage differential power amplifier circuit also includes a second differential power amplifier. The second differential power amplifier is biased by a second bias voltage to be activated only when an instantaneous power level of the RF signal is higher than or equal to a first power threshold to amplify the second differential signal based on the supply voltage. The multi-stage differential power amplifier circuit also includes an output stage circuit. The output stage circuit is configured to modulate a load impedance at an output of the first differential power amplifier when the instantaneous power level of the RF signal is higher than the first power threshold but lower than or equal to a second power threshold. The output stage circuit is also configured to constantly keep the load impedance at the output of the first differential power amplifier when the instantaneous power level of the RF signal is lower than or equal to the first power threshold or higher than the second power threshold. The multi-stage differential power amplifier circuit also includes a control circuit. The control circuit is configured to generate the first bias voltage and the second bias voltage based on the instantaneous power level of the RF signal to thereby bias the first differential power amplifier and the second differential power amplifier, respectively.

In another aspect, a method for controlling a multi-stage differential power amplifier circuit is provided. The method includes amplifying, using a driver stage circuit, an RF signal and outputting a first differential signal and a second differential signal each comprising a respective non-inverting signal and a respective inverting signal. The method also includes biasing a first differential power amplifier by a first bias voltage such that the first differential power amplifier is always active to amplify the first differential signal based on a supply voltage. The method also includes biasing a second differential power amplifier by a second bias voltage such that the second differential power amplifier is activated only when an instantaneous power level of the RF signal is higher than or equal to a first power threshold to amplify the second differential signal based on the supply voltage. The method also includes modulating, by an output stage circuit, a load impedance at an output of the first differential power amplifier when the instantaneous power level of the RF signal is higher than the first power threshold but lower than or equal to a second power threshold. The method also includes constantly keeping, by the output stage circuit, the load impedance at the output of the first differential power amplifier when the instantaneous power level of the RF signal is lower than or equal to the first power threshold or higher than the second power threshold. The method also includes generating the first bias voltage and the second bias voltage based on the instantaneous power level of the RF signal to thereby bias the first differential power amplifier and the second differential power amplifier, respectively.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein a multi-stage differential power amplifier circuit can be self-controlled according to various embodiments of the present disclosure;

FIGS. 2A and 2B are graphic diagrams providing exemplary illustrations of operating principles of the power management circuit of FIG. 1;

FIG. 3 is a schematic diagram providing an exemplary illustration of the multi-stage differential power amplifier circuit in FIG. 1 configured according to an embodiment of the present disclosure;

FIG. 4 is a schematic diagram of an exemplary control circuit that can be provided in the multi-stage differential power amplifier circuit in FIG. 1;

FIGS. 5A and 5B are graphic diagrams providing exemplary illustrations as to how the control circuit in FIG. 4 controls various circuits in the multi-stage differential power amplifier circuit of FIG. 3;

FIG. 6 is a schematic diagram of an exemplary communication device wherein the power management circuit of FIG. 1 can be provided; and

FIG. 7 is a flowchart of an exemplary process for controlling the multi-stage differential power amplifier circuit in FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to a mechanism for controlling a multi-stage differential power amplifier circuit. The multi-stage differential power amplifier circuit includes a driver stage circuit and a pair of differential power amplifiers. The driver stage circuit generates a pair of differential signals from a radio frequency (RF) signal. The pair of differential power amplifiers are each biased by a respective bias voltage to amplify a respective one of the pair of differential signals. Specifically, a first differential power amplifier is so biased to always be active, whereas a second differential power amplifier is so biased to only be active as needed. In embodiments disclosed herein, a control circuit is configured to detect an instantaneous power level of the RF signal and generate the bias voltages accordingly. As such, the multi-stage differential power amplifier circuit can be self-sufficient in controlling the pair of differential power amplifiers, thus helping to improve transmission efficiency in a wireless device and reduce the need for time-consuming calibration for part-to-part variation.

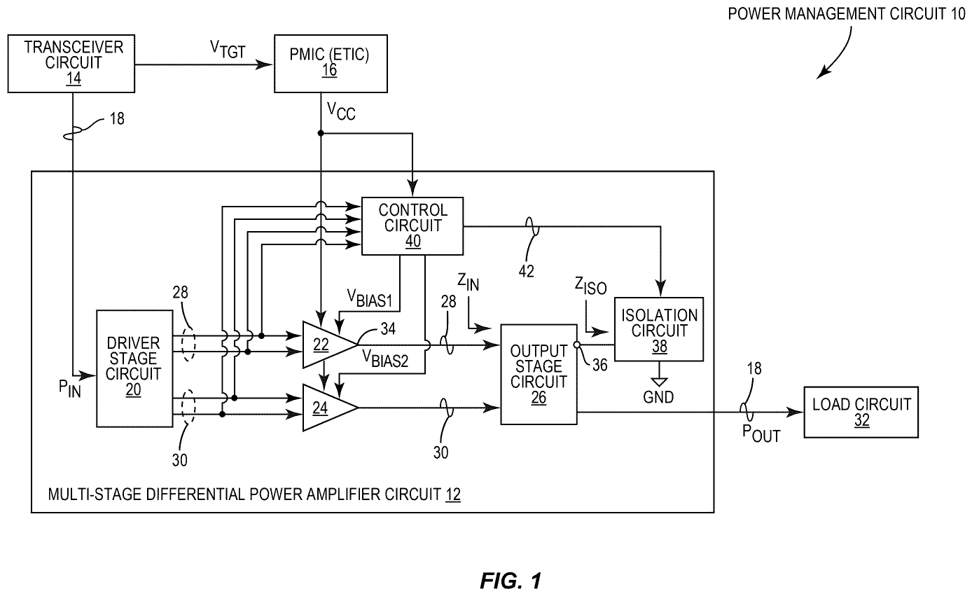

FIG. 1 is a schematic diagram of an exemplary power management circuit 10 wherein a multi-stage differential power amplifier circuit 12 can be controlled according to various embodiments of the present disclosure. In context of the present disclosure, a multi-stage differential power amplifier circuit refers generally to a power amplifier circuit that includes two or more amplification stages (e.g., driver stage and output stage). In addition, at least one of the amplification stages in the multi-stage differential power amplifier circuit can include a differential power amplifier(s) configured to amplify a differential signal consisting of a pair of opposite-phased signals (e.g., a 0° vs. 180° differential signal or a 90° vs. 270° differential signal). For the purpose of distinction, one of the opposite-phased signals (e.g., a signal with 0° or 90° phase) is referred to herein as a non-inverting signal, whereas another one of the opposite-phased signals (e.g., a signal with 180° or 270° phase) is referred to herein as an inverting signal relative to the non-inverting signal in the respective differential signal.

The power management circuit 10 includes a transceiver circuit 14 and a power management integrated circuit (PMIC) 16. The transceiver circuit 14 is configured to generate an RF signal 18 having a time-variant input power P_{IN} and a target voltage V_{TGT} that tracks the time-variant input power P_{IN} of the RF signal 18. The PMIC 16 is configured to generate a supply voltage V_{CC}, such as an envelope tracking (ET) voltage, based on the target voltage V_{TGT}.

In an embodiment, the multi-stage differential power amplifier circuit 12 includes a driver stage circuit 20, a first differential power amplifier 22, a second differential power amplifier 24, and an output stage circuit 26. The driver stage circuit 20 is configured to amplify the RF signal 18 based on the supply voltage V_{CC} and output a first differential signal 28 and a second differential signal 30 based on the amplified RF signal 18. The first differential power amplifier 22 is biased by a first bias voltage V_{BIAS1} to always be active to further amplify the first differential signal 28, whereas the second differential power amplifier 24 is biased by a second bias voltage V_{BIAS2} to be conditionally activated to further amplify the second differential signal 30. The output stage circuit 26 is configured to serve dual purposes. On one hand, the output stage circuit 26 combines the amplified first differential signal 28 and the amplified second differential signal 30 (if available) to thereby output the amplified RF signal 18 to a coupled load circuit 32 (e.g., an RF frontend circuit). On the other hand, the output stage circuit 26 is configured to manipulate a load impedance Z_{IN} at an output 34 of the first differential power amplifier 22.

The output stage circuit 26 includes an isolation port 36 that is terminated by a termination impedance Z_{ISO}. In an embodiment, the multi-stage differential power amplifier circuit 12 also includes an isolation circuit 38, which is coupled to the isolation port 36 to manipulate the termination impedance Z_{ISO}. The multi-stage differential power amplifier circuit 12 further includes a control circuit 40. The control circuit 40 is configured to control the first differential power amplifier 22 and the second differential power amplifier 24 via the first bias voltage V_{BIAS1} and the second bias voltage V_{BIAS2}, respectively. The control circuit 40 is further configured to control the isolation circuit 38 via an isolation control signal 42.

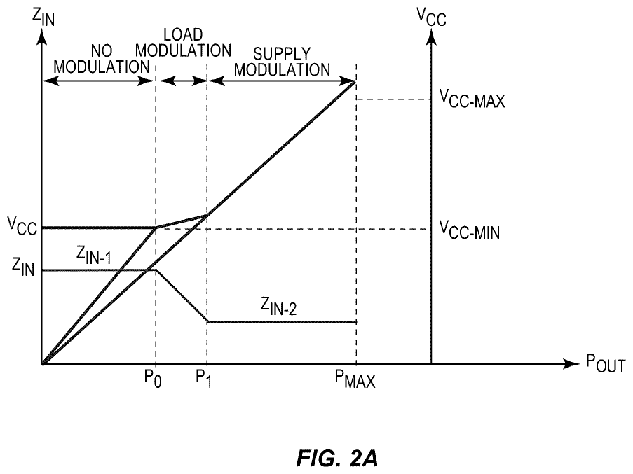

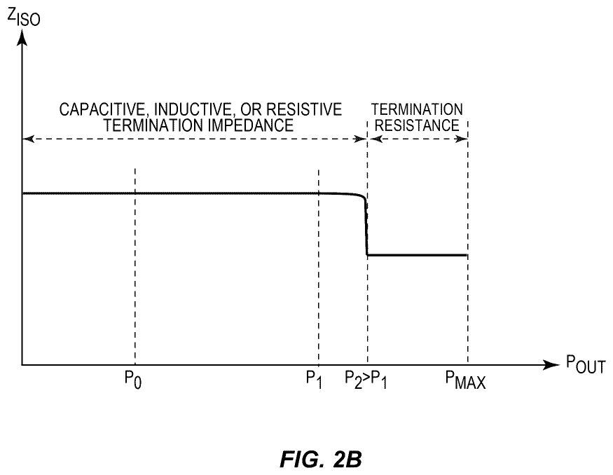

FIGS. 2A and 2B are graphic diagrams providing exemplary illustrations of important operating principles of the power management circuit 10 of FIG. 1. Common elements between FIGS. 1, 2A, and 2B are shown therein with common element numbers and will not be re-described herein.

FIG. 2A illustrates how the output stage circuit 26 manipulates the load impedance P_{IN} and how the PMIC 16 adapts the supply voltage V_{CC} in accordance with an instantaneous power level of the RF signal 18. Herein, the output stage circuit 26 modulates the load impedance Z_{IN} based on a first power threshold P₀ and a second power threshold P₁. In an embodiment, the second power threshold P₁ is approximately 8 to 10 dBs below a maximum power level P_{MAX} of the RF signal 18 and the first power threshold P₀ is approximately 4 to 6 dBs below the second power threshold P₁.

When an instantaneous power level of the RF signal 18 is lower than or equal to the first power threshold P₀, the output stage circuit 26 modulates the load impedance Z_{IN} at a first fixed level Z_{IN-1}. When the instantaneous power level of the RF signal 18 is higher than the second power threshold P₁, the output stage circuit 26 modulates the load impedance Z_{IN} at a second fixed level Z_{IN-2} (Z_{IN-2}<Z_{IN-1}). When the instantaneous power level of the RF signal 18 is higher than the first power threshold P₀ but lower than or equal to the second power threshold P₁, the output stage circuit 26 modulates the load impedance Z_{IN} in accordance with the instantaneous power level of the RF signal 18.

In general, modulating the load impedance Z_{IN} can be performed by any passive impedance modulation circuits like the output stage circuit 26. For a more in-depth description and specific examples of using a passive impedance modulation circuit to modulate the load impedance Z_{IN}, please refer to PCT Patent Application Number PCT/US2025/033449, entitled “CONTROLLING A DUAL-AMPLIFIER POWER AMPLIFIER CIRCUIT IN A POWER MANAGEMENT CIRCUIT,” and PCT Patent Application Number PCT/US2025/041493, entitled “REDUCING SUPPLY VOLTAGE RANGE IN A POWER MANAGEMENT CIRCUIT.”

In addition to manipulating the load impedance Z_{IN} at the output 34 of the first differential power amplifier 22, the PMIC 16 is configured to adapt the supply voltage V_{CC} in accordance with the instantaneous power level of the RF signal 18. Specifically, when the instantaneous power level of the RF signal 18 is lower than or equal to the first power threshold P₀, the PMIC 16 constantly maintains the supply voltage V_{CC} at a minimum voltage level V_{CC-MIN} independent of how the instantaneous power level of the RF signal 18 varies. Herein, the second differential power amplifier 24 is deactivated by the second bias voltage V_{BIAS2}, while the first differential power amplifier 22 is activated by the first bias voltage V_{BIAS1} to amplify the RF signal 18 based on the supply voltage V_{CC}. As such, the multi-stage differential power amplifier circuit 12 is said to operate without modulation (a.k.a. no modulation).

When the instantaneous power level of the RF signal 18 is higher than the first power threshold P₀ but lower than or equal to the second power threshold P₁, the first differential power amplifier 22 will be biased by the first bias voltage V_{BIAS1} to operate under full compression and the second differential power amplifier 24 will be activated by the second bias voltage V_{BIAS2}. In the meantime, since the output stage circuit 26 is modulating the load impedance Z_{IN}, the multi-stage differential power amplifier circuit 12 is said to operate based on load modulation. Depending on whether the first power threshold P₀ is equal to or less than one-half (½) of the second power threshold P₁, the PMIC 16 may either maintain the supply voltage V_{CC} at the minimum voltage level V_{CC-MIN} or slowly increase the supply voltage V_{CC}.

When the instantaneous power level of the RF signal 18 becomes higher than the second power threshold P₁, the second differential power amplifier 24 will be biased by the second bias voltage V_{BIAS2} to operate under full compression. The PMIC 16 will once again generate the supply voltage V_{CC} in accordance with the instantaneous power of the RF signal 18. In this regard, the multi-stage differential power amplifier circuit 12 will operate based on supply modulation. In the meantime, the first differential power amplifier 22 and the second differential power amplifier 24 will be biased equally by the first bias voltage V_{BIAS1} and the second bias voltage V_{BIAS2} (V_{BIAS1}=V_{BIAS2}) to each deliver one-half (½) of the time-variant output power P_{OUT} and collectively drive the time-variant output power P_{OUT} toward the peak power level P_{MAX}.

FIG. 2B illustrates how the isolation circuit 38 can be controlled to generate the termination impedance Z_{ISO} in accordance with the instantaneous power level of the RF signal 18. When the instantaneous power level of the RF signal 18 is lower than or equal to the second power threshold P₁, the isolation circuit 38 may present the termination impedance Z_{ISO} as a capacitive impedance, an inductive impedance, or a resistive impedance. By terminating the isolation port 36 with the capacitive impedance, the inductive impedance, or the resistive impedance, the output stage circuit 26 can thus modulate the load impedance Z_{IN} as described above in FIG. 2A.

However, when the output stage circuit 26 is modulating the load impedance Z_{IN}, the time-variant output power P_{OUT} may be reflected from the coupled load circuit 32. As a result, the multi-stage differential power amplifier circuit 12 can suffer a worsened VSWR. Understandably from the previous discussion in FIG. 2A, the output stage circuit 26 will keep the load impedance Z_{IN} constant when the instantaneous power level of the RF signal 18 is higher than the second power threshold P₁. As such, in various embodiments, the isolation circuit 38 can be configured to change the termination impedance Z_{ISO} from the capacitive impedance, the inductive impedance, or the resistive impedance toward a termination resistance when the instantaneous power level of the RF signal 18 is higher than the second power threshold P₁.

Specifically, the isolation circuit 38 may be configured to transition from the capacitance impedance, the inductive impedance, or the resistive impedance toward the termination resistance when the instantaneous power level of the RF signal 18 is higher than the second power threshold P₁ but lower than a third power threshold P₂ that is approximately 0.5 to 1 dB higher than the second power threshold P₁. When the instantaneous power level of the RF signal 18 is higher than or equal to the third power threshold P₂, the isolation circuit 38 will only present the termination resistance at the isolation port 36 as the termination impedance Z_{ISO}. By presenting the termination impedance Z_{ISO} as the termination resistance, the reflected power of the RF signal 18 can be reflected at opposite phase angles to the first differential power amplifier 22 and the second differential power amplifier 24, thus helping to improve VSWR immunity of the multi-stage differential power amplifier circuit 12.

In this regard, it is critical to effectively control the multi-stage differential power amplifier circuit 12 to satisfy the important operating aspects described in FIGS. 2A and 2B. As discussed in detail below, the control circuit 40 can detect the instantaneous power level of the RF signal 18 to thereby determine the first bias voltage V_{BIAS1}, the second bias voltage V_{BIAS2}, and the isolation control signal 42. As a result, the multi-stage differential power amplifier circuit 12 can become self-sufficient in controlling various aspects of operation without unnecessary external intervention, thus helping to reduce the need for time-consuming calibration for part-to-part variation.

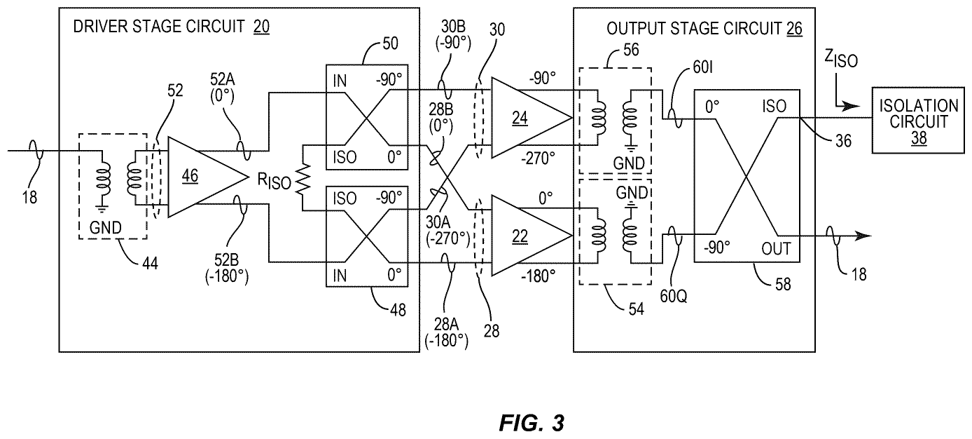

FIG. 3 is a schematic diagram providing an exemplary illustration of the driver stage circuit 20, the first differential power amplifier 22, the second differential power amplifier 24, and the output stage circuit 26 in the multi-stage differential power amplifier circuit 12 in FIG. 1 configured according to an embodiment of the present disclosure. Common elements between FIGS. 1 and 3 are shown therein with common element numbers and will not be re-described herein.

Herein, the driver stage circuit 20 includes an unbalanced-to-balanced transformer 44, a driver stage differential power amplifier 46, a first input hybrid coupler 48, and a second input hybrid coupler 50. In an embodiment, the unbalanced-to-balanced transformer 44 is configured to convert the RF signal 18 into a driver stage differential signal 52, which includes a non-inverting driver stage signal 52A associated with a 0° phase offset and an inverting driver stage signal 52B associated with a −180° phase offset relative to the non-inverting driver stage signal 52A. The driver stage differential power amplifier 46 is configured to amplify both the non-inverting driver stage signal 52A and the inverting driver stage signal 52B in the driver stage differential signal 52.

The first input hybrid coupler 48 and the second input hybrid coupler 50 each includes a respective input port (denoted as “IN”), a respective isolation port (denoted as “ISO”), a respective quadrature output (denoted as “−90°), and a respective in-phase output (denoted as “0°”). In an embodiment, the respective isolation port (ISO) in the first input hybrid coupler 48 and the respective isolation port (ISO) in the second input hybrid coupler 50 are both coupled to an isolation resistor R_{ISO}.

The first input hybrid coupler 48 receives the inverting driver stage signal 52B, as amplified by the driver stage differential power amplifier 46, via the respective input port (IN). Accordingly, the first input hybrid coupler 48 is configured to generate a respective inverting signal 28A, which is in-phase (e.g., −180°) to the inverting driver stage signal 52B, in the first differential signal 28 via the respective in-phase output (0°) and a respective inverting signal 30A, which is quadrature (e.g., −270°) to the inverting driver stage signal 52B, in the second differential signal 30 via the respective quadrature-phase output (−90°).

The second input hybrid coupler 50 receives the amplified non-inverting driver stage signal 52A via the respective input port (IN). Accordingly, the second input hybrid coupler 50 is configured to generate a respective non-inverting signal 28B, which is in-phase (e.g., 0°) to the non-inverting driver stage signal 52A, in the first differential signal 28 via the respective in-phase output (0°) and a respective non-inverting signal 30B, which is quadrature (e.g., −90°) to the non-inverting driver stage signal 52A, in the second differential signal 30 via the respective quadrature output (−90°). In this regard, the first differential signal 28, which is associated with a 0° vs. −180 ° phase offset, can be said to be in a quadrature relationship to the second differential signal 30 that is associated with a −90° vs. −270° phase offset.

The driver stage circuit 20 is coupled to the first differential power amplifier 22 and the second differential power amplifier 24. As described earlier, the first differential power amplifier 22 is always activated to amplify the first differential signal 28, whereas the second differential power amplifier 24 is only activated as needed to amplify the second differential signal 30.

In an embodiment, the output stage circuit 26 includes a first balanced-to-unbalanced transformer 54, a second balanced-to-unbalanced transformer 56, and an output hybrid coupler 58. The first balanced-to-unbalanced transformer 54 is configured to convert the amplified first differential signal 28 into a quadrature output stage signal 60Q and the second balanced-to-unbalanced transformer 56 is configured to convert the amplified second differential signal 30 into an in-phase output stage signal 60I.

The output hybrid coupler 58 includes a respective in-phase input (denoted as “0°”), a respective quadrature input (denoted as “−90°), the respective isolation port 36 (also denoted as “ISO”), and a respective output port (denoted as “OUT”). In an embodiment, the isolation port 36 is coupled to the isolation circuit 38 that generates the termination impedance Z_{ISO}. The output hybrid coupler 58 receives the in-phase output stage signal 60I and the quadrature output stage signal 60Q via the in-phase input (0°) and the quadrature input (−90°), respectively. Accordingly, the output hybrid coupler 58 can combine the in-phase output stage signal 60I and the quadrature output stage signal 60Q to thereby output the amplified RF signal 18 via the output port (OUT).

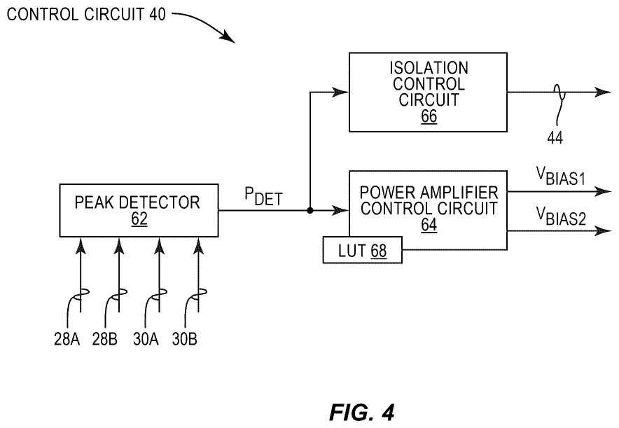

As described above, the first differential power amplifier 22, the second differential power amplifier 24, and the isolation circuit 38 are all controlled by the control circuit 40 in the multi-stage differential power amplifier circuit 12. FIG. 4 is a schematic diagram providing an exemplary illustration of the control circuit 40 in the multi-stage differential power amplifier circuit 12 in FIG. 1 configured to detect the instantaneous power level of the RF signal 18 and control the first differential power amplifier 22, the second differential power amplifier 24, and the isolation circuit 38. Common elements between FIGS. 1, 3, and 4 are shown therein with common element numbers and will not be re-described herein.

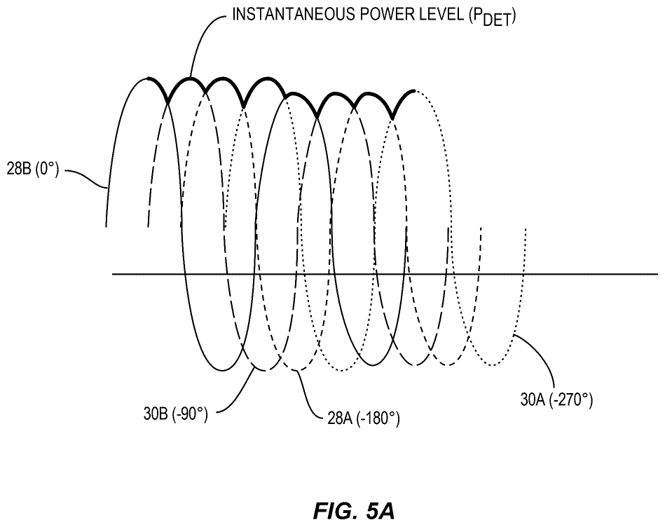

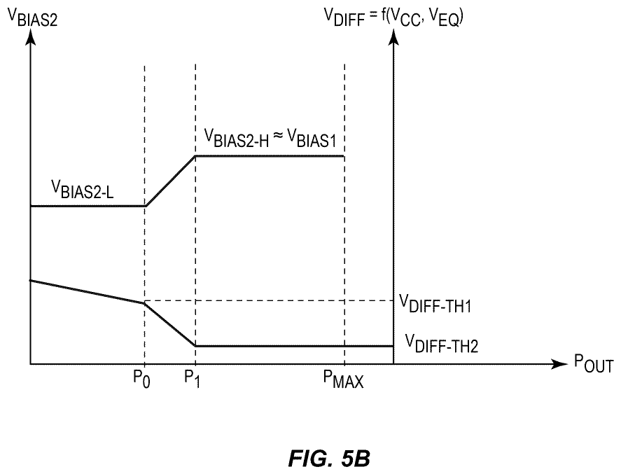

Herein, the control circuit 40 includes a peak detector 62, a power amplifier control circuit 64, and an isolation control circuit 66. The peak detector 62 is configured to detect the instantaneous power level of the RF signal 18. FIG. 5A is a graphic diagram providing an exemplary illustration as to how the peak detector 62 can detect the instantaneous power level of the RF signal 18.

As illustrated in FIG. 5A, the peak detector 62 can detect the instantaneous power level of the RF signal 18 (denoted as “P_{DET}”) from the respective inverting signal 28A and the respective non-inverting signal 28B in the first differential signal 28 and the respective inverting signal 30A and the respective non-inverting signal 30B in the second differential signal 30. Understandably, by extracting the instantaneous power level of the RF signal 18 from the first differential signal 28 and the second differential signal 30, it is equivalent to increasing the frequency of the RF signal 18 by four times. As a result, it is possible to reduce the filtering requirement in the peak detector 62 and, therefore, the group delay associated with determining the instantaneous power level of the RF signal 18.

With reference back to FIG. 4, the power amplifier control circuit 64 is configured to generate the first bias voltage V_{BIAS1} and the second bias voltage V_{BIAS2} to thereby bias the first differential power amplifier 22 and the second differential power amplifier 24, respectively. As previously described, because the first differential power amplifier 22 is always active, the power amplifier control circuit 64 can thus generate the first bias voltage V_{BIAS1} independent of the instantaneous power level of the RF signal 18. As such, since the second differential power amplifier 24 is only activated when the instantaneous power level of the RF signal 18 is above the first power threshold P₀, the power amplifier control circuit 64 will need to generate the second bias voltage V_{BIAS2} in accordance with the instantaneous power level of the RF signal 18.

In a first embodiment, the power amplifier control circuit 64 determines the second bias voltage V_{BIAS2} to debias the second differential power amplifier 24 when the detected instantaneous power level of the RF signal 18 is lower than or equal to the first power threshold P₀. When the instantaneous power level of the RF signal 18 is higher than the first power threshold P₀ but lower than or equal to the second power threshold P₁, the power amplifier control circuit 64 will map the instantaneous power level of the RF signal 18 to various levels of the second bias voltage V_{BIAS2}. In a non-limiting example, the power amplifier control circuit 64 can perform such mapping using a lookup table (LUT) 68. When the instantaneous power level of the RF signal 18 is higher than the second power threshold P₁, the power amplifier control circuit 64 will determine the second bias voltage V_{BIAS2} to be equal to the first bias voltage V_{BIAS1} such that both the first differential power amplifier 22 and the second differential power amplifier 24 can be equally biased.

In a second embodiment, the power amplifier control circuit 64 can also determine the second bias voltage V_{BIAS2} based on a mathematical relationship between the supply voltage V_{CC} and the instantaneous power level of the RF signal 18. FIG. 5B is a graphic diagram providing an exemplary illustration as to how the power amplifier control circuit 64 can mathematically determine the second bias voltage V_{BIAS2}.

Specifically, the power amplifier control circuit 64 can determine an equivalent voltage (denoted as “V_{EQ}”) that corresponds to the instantaneous power level (P_{DET}) of the RF signal 18. As an example, the power amplifier control circuit 64 can determine the equivalent voltage V_{EQ} from the instantaneous power level P_{DET} in accordance with well-established mathematical equations. The power amplifier control circuit 64 can then determine a voltage differential V_{DIFF} as a function of the supply voltage V_{CC} and the equivalent voltage V_{EQ} based on any of the equations (Eq. 1 and Eq. 2) below.

V_{DIFF}=s*V_{CC}−V_{EQ} (Eq. 1)

V_{DIFF}=V_{CC}−s*V_{EQ} (Eq. 2)

In the equations (Eq. 1 & Eq. 2), s represents a scaling factor. As illustrated in FIG. 5B, when the voltage differential V_{DIFF} is above a first bias threshold V_{DIFF-TH1}, the power amplifier control circuit 64 determines the second bias voltage V_{BIAS2} at a first fixed level V_{BIAS2-L}. Herein, the first fixed level V_{BIAS2-L} is low enough to debias, and thus deactivate, the second differential power amplifier 24.

When the voltage differential V_{DIFF} is below a second bias threshold V_{DIFF-TH2} (V_{DIFF-TH2}<V_{DIFF-TH1}), the power amplifier control circuit 64 will determine the second bias voltage V_{BIAS2} at a second fixed level V_{BIAS2-H} (V_{BIAS2-H}>V_{BIAS2-L}). In a non-limiting example, the second fixed level V_{BIAS2-H} can be equal to the first bias voltage V_{BIAS1} such that the first differential power amplifier 22 and the second differential power amplifier 24 can be equally biased. In this regard, both the first differential power amplifier 22 and the second differential power amplifier 24 will operate in compression. Accordingly, the output stage circuit 26 will modulate the load impedance Z_{IN} and the multi-stage differential power amplifier circuit 12 will operate based on the supply modulation.

When the voltage differential V_{DIFF} is lower than or equal to the first bias threshold V_{DIFF-TH1} but higher than or equal to the second bias threshold V_{DIFF-TH2}, the power amplifier control circuit 64 will increase the second bias voltage V_{BIAS2} from the first fixed level V_{BIAS2-L} toward the second fixed level V_{BIAS2-H}. In this regard, the first differential power amplifier 22 and the second differential power amplifier 24 are unequally biased. Accordingly, the output stage circuit 26 will modulate the load impedance Z_{IN} and the multi-stage differential power amplifier circuit 12 will operate based on the load modulation.

As mentioned earlier in FIG. 3, when the instantaneous power level of the RF signal 18 is lower than or equal to the second power threshold P₁, the isolation circuit 38 will present the termination impedance Z_{ISO} as a capacitive impedance, an inductive impedance, or a resistive impedance, depending on absolute phases of the in-phase output stage signal 60I and the quadrature output stage signal 60Q. In this regard, the isolation control circuit 66 in FIG. 4 is configured to determine the termination impedance Z_{ISO} as the capacitive termination impedance, the inductive termination impedance, or the resistive termination impedance in accordance with the instantaneous power level (P_{DET}) of the RF signal 18. Accordingly, the isolation control circuit 66 can control the isolation circuit 38 to present the determined termination impedance at the isolation port 36 of the output hybrid coupler 58.

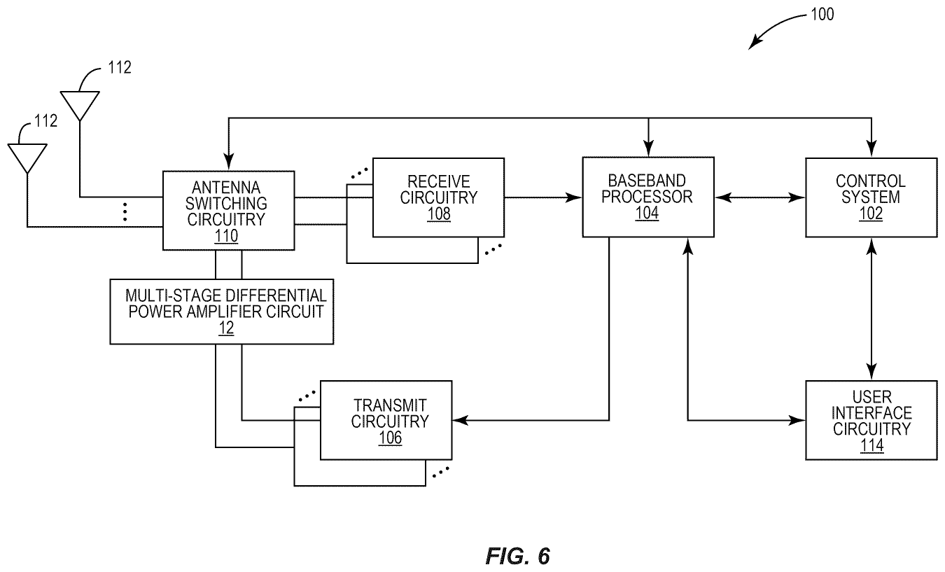

The power management circuit 10 of FIG. 1 can be provided in a communication device to support the embodiments described above. In this regard, FIG. 6 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can function as the transceiver circuit 14 in FIG. 1. Accordingly, the multi-stage differential power amplifier circuit 12 can be provided between the transmit circuitry 106 and the antenna switching circuitry 110.

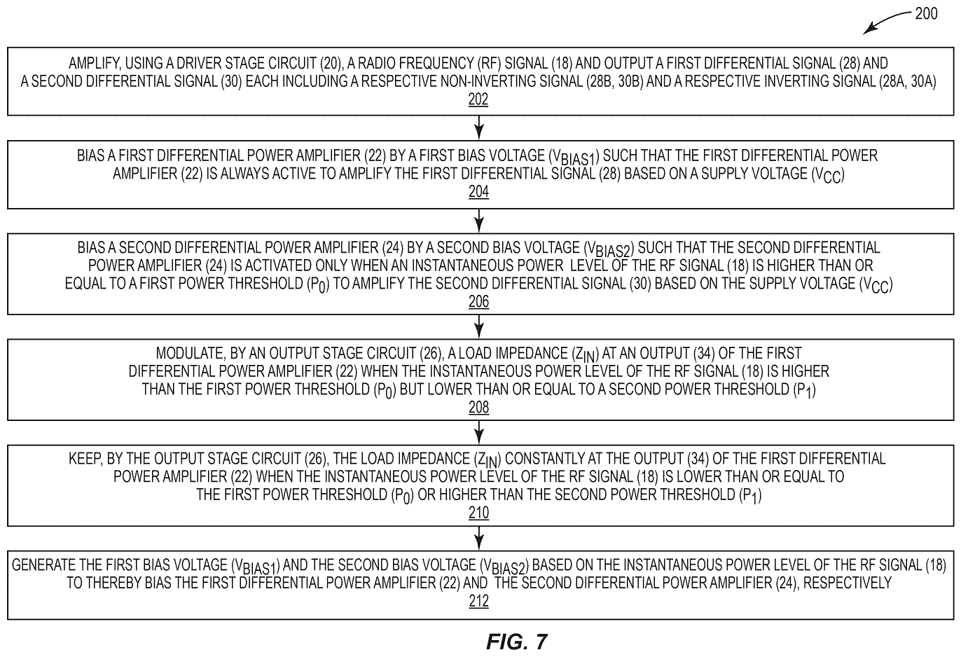

In an embodiment, it is possible to control the power management circuit 10 of FIG. 1 in accordance with a process. In this regard, FIG. 7 is a flowchart of an exemplary process 200 for controlling the multi-stage differential power amplifier circuit 12 in FIG. 1.

Herein, the process 200 includes amplifying, using the driver stage circuit 20, the RF signal 18 and outputting the first differential signal 28 and the second differential signal 30 each including the respective non-inverting signal 28B or 30B and the respective inverting signal 28A or 30A (step 202). The process 200 also includes biasing the first differential power amplifier 22 by the first bias voltage V_{BIAS1} such that the first differential power amplifier 22 is always active to amplify the first differential signal 28 based on the supply voltage V_{CC} (step 204). The process 200 also includes biasing the second differential power amplifier 24 by the second bias voltage V_{BIAS2} such that the second differential power amplifier 24 is activated only when the instantaneous power level of the RF signal 18 is higher than or equal to the first power threshold P₀ to amplify the second differential signal 30 based on the supply voltage V_{CC} (step 206). The process 200 also includes modulating, by the output stage circuit 26, the load impedance Z_{IN} at the output 34 of the first differential power amplifier 22 when the instantaneous power level of the RF signal 18 is higher than the first power threshold P₀ but lower than or equal to the second power threshold P₁ (step 208). The process 200 also includes constantly keeping, by the output stage circuit 26, the load impedance Z_{IN} at the output 34 of the first differential power amplifier 22 when the instantaneous power level of the RF signal 18 is lower than or equal to the first power threshold P₀ or higher than the second power threshold P₁ (step 210). The process 200 also includes generating the first bias voltage V_{BIAS1} and the second bias voltage V_{BIAS2} based on the instantaneous power level of the RF signal 18 to thereby bias the first differential power amplifier 22 and the second differential power amplifier 24, respectively (step 212).

Those skilled in the art will recognize improvements and modifications to the preferred embodiments of the present disclosure. All such improvements and modifications are considered within the scope of the concepts disclosed herein and the claims that follow.

What is claimed is:

1. A multi-stage differential power amplifier circuit comprising:
a driver stage circuit configured to amplify a radio frequency (RF) signal and output a first differential signal and a second differential signal each comprising a respective non-inverting signal and a respective inverting signal;
a first differential power amplifier biased by a first bias voltage to always be active to amplify the first differential signal based on a supply voltage;
a second differential power amplifier biased by a second bias voltage to be activated only when an instantaneous power level of the RF signal is higher than a first power threshold to amplify the second differential signal based on the supply voltage;
an output stage circuit configured to:
modulate a load impedance at an output of the first differential power amplifier when the instantaneous power level of the RF signal is higher than the first power threshold but lower than or equal to a second power threshold; and
constantly keep the load impedance at the output of the first differential power amplifier when the instantaneous power level of the RF signal is lower than or equal to the first power threshold or higher than the second power threshold; and
a control circuit configured to generate the first bias voltage and the second bias voltage based on the instantaneous power level of the RF signal to thereby bias the first differential power amplifier and the second differential power amplifier, respectively.

2. The multi-stage differential power amplifier circuit of claim 1, wherein the control circuit comprises:
a peak detector configured to detect the instantaneous power level of the RF signal based on the respective non-inverting signal and the respective inverting signal in each of the first differential signal and the second differential signal; and
a power amplifier control circuit configured to generate the first bias voltage and the second bias voltage based on the detected instantaneous power level of the RF signal to thereby bias the first differential power amplifier and the second differential power amplifier, respectively.

3. The multi-stage differential power amplifier circuit of claim 2, wherein the power amplifier control circuit is further configured to:
determine the second bias voltage to debias the second differential power amplifier when the detected instantaneous power level of the RF signal is lower than or equal to the first power threshold;
map the detected instantaneous power level of the RF signal to various levels of the second bias voltage when the detected instantaneous power level is higher than the first power threshold but lower than or equal to the second power threshold; and
determine the second bias voltage to be equal to the first bias voltage when the detected instantaneous power level of the RF signal is higher than the second power threshold.

4. The multi-stage differential power amplifier circuit of claim 2, wherein the control circuit is further configured to:
determine a voltage differential between the supply voltage and an equivalent voltage corresponding to the detected instantaneous power level of the RF signal;
determine the second bias voltage at a first fixed level to debias the second differential power amplifier when the voltage differential is above a first bias threshold;
determine the second bias voltage at a second fixed level higher than the first fixed level to equally bias the first differential power amplifier and the second differential power amplifier when the voltage differential is below a second bias threshold lower than the first bias threshold; and
increase the second bias voltage from the first fixed level toward the second fixed level to unequally bias the first differential power amplifier and the second differential power amplifier when the voltage differential is lower than or equal to the first bias threshold but higher than or equal to the second bias threshold.

5. The multi-stage differential power amplifier circuit of claim 4, wherein the power amplifier control circuit is further configured to determine the voltage differential as: V_{DIFF}=s*V_{CC}−V_{EQ}, wherein:
V_{DIFF} represents the voltage differential;
V_{CC} represents the supply voltage;
V_{EQ} represents the equivalent voltage corresponding to the detected instantaneous power level of the RF signal; and
s represents a scaling factor.

6. The multi-stage differential power amplifier circuit of claim 1, further comprising an isolation circuit configured to present a termination impedance at an isolation port of the output stage circuit.

7. The multi-stage differential power amplifier circuit of claim 6, wherein the control circuit comprises an isolation control circuit configured to:
determine the termination impedance as one of a capacitive termination impedance, an inductive termination impedance, and a resistive termination impedance in accordance with the instantaneous power level of the RF signal; and
control the isolation circuit to present the determined termination impedance at the isolation port of the output stage circuit.

8. A wireless device comprising a multi-stage differential power amplifier circuit, the multi-stage differential power amplifier circuit comprises:
a driver stage circuit configured to amplify a radio frequency (RF) signal and output a first differential signal and a second differential signal each comprising a respective non-inverting signal and a respective inverting signal;
a first differential power amplifier biased by a first bias voltage to always be active to amplify the first differential signal based on a supply voltage;
a second differential power amplifier biased by a second bias voltage to be activated only when an instantaneous power level of the RF signal is higher than or equal to a first power threshold to amplify the second differential signal based on the supply voltage;
an output stage circuit configured to:
modulate a load impedance at an output of the first differential power amplifier when the instantaneous power level of the RF signal is higher than the first power threshold but lower than or equal to a second power threshold; and
constantly keep the load impedance at the output of the first differential power amplifier when the instantaneous power level of the RF signal is lower than or equal to the first power threshold or higher than the second power threshold; and
a control circuit configured to generate the first bias voltage and the second bias voltage based on the instantaneous power level of the RF signal to thereby bias the first differential power amplifier and the second differential power amplifier, respectively.

9. The wireless device of claim 8, wherein the control circuit comprises:
a peak detector configured to detect the instantaneous power level of the RF signal based on the respective non-inverting signal and the respective inverting signal in each of the first differential signal and the second differential signal; and
a power amplifier control circuit configured to generate the first bias voltage and the second bias voltage based on the detected instantaneous power level of the RF signal to thereby bias the first differential power amplifier and the second differential power amplifier, respectively.

10. The wireless device of claim 9, wherein the power amplifier control circuit is further configured to:
determine the second bias voltage to debias the second differential power amplifier when the detected instantaneous power level of the RF signal is lower than or equal to the first power threshold;
map the detected instantaneous power level of the RF signal to various levels of the second bias voltage when the detected instantaneous power level is higher than the first power threshold but lower than or equal to the second power threshold; and
determine the second bias voltage to be equal to the first bias voltage when the detected instantaneous power level of the RF signal is higher than the second power threshold.

11. The wireless device of claim 9, wherein the control circuit is further configured to:
determine a voltage differential between the supply voltage and an equivalent voltage corresponding to the detected instantaneous power level of the RF signal;
determine the second bias voltage at a first fixed level to debias the second differential power amplifier when the voltage differential is above a first bias threshold;
determine the second bias voltage at a second fixed level higher than the first fixed level to equally bias the first differential power amplifier and the second differential power amplifier when the voltage differential is below a second bias threshold lower than the first bias threshold; and
increase the second bias voltage from the first fixed level toward the second fixed level to unequally bias the first differential power amplifier and the second differential power amplifier when the voltage differential is lower than or equal to the first bias threshold but higher than or equal to the second bias threshold.

12. The wireless device of claim 11, wherein the power amplifier control circuit is further configured to determine the voltage differential as: V_{DIFF}=s*V_{CC}−V_{EQ}, wherein:
V_{DIFF} represents the voltage differential;
V_{CC} represents the supply voltage;
V_{EQ} represents the equivalent voltage corresponding to the detected instantaneous power level of the RF signal; and
s represents a scaling factor.

13. The wireless device of claim 8, further comprising an isolation circuit configured to present a termination impedance at an isolation port of the output stage circuit.

14. The wireless device of claim 13, wherein the control circuit comprises an isolation control circuit configured to:
determine the termination impedance as one of a capacitive termination impedance, an inductive termination impedance, and a resistive termination impedance in accordance with the instantaneous power level of the RF signal; and
control the isolation circuit to present the determined termination impedance at the isolation port of the output stage circuit.

15. A method for controlling a multi-stage differential power amplifier circuit comprising:
amplifying, using a driver stage circuit, a radio frequency (RF) signal and outputting a first differential signal and a second differential signal each comprising a respective non-inverting signal and a respective inverting signal;
biasing a first differential power amplifier by a first bias voltage such that the first differential power amplifier is always active to amplify the first differential signal based on a supply voltage;
biasing a second differential power amplifier by a second bias voltage such that the second differential power amplifier is activated only when an instantaneous power level of the RF signal is higher than a first power threshold to amplify the second differential signal based on the supply voltage;
modulating, by an output stage circuit, a load impedance at an output of the first differential power amplifier when the instantaneous power level of the RF signal is higher than the first power threshold but lower than or equal to a second power threshold;
constantly keeping, by the output stage circuit, the load impedance at the output of the first differential power amplifier when the instantaneous power level of the RF signal is lower than or equal to the first power threshold or higher than the second power threshold; and
generating the first bias voltage and the second bias voltage based on the instantaneous power level of the RF signal to thereby bias the first differential power amplifier and the second differential power amplifier, respectively.

16. The method of claim 15, further comprising:
detecting the instantaneous power level of the RF signal based on the respective non-inverting signal and the respective inverting signal in each of the first differential signal and the second differential signal; and
generating the first bias voltage and the second bias voltage based on the detected instantaneous power level of the RF signal to thereby bias the first differential power amplifier and the second differential power amplifier, respectively.

17. The method of claim 16, further comprising:
determining the second bias voltage to debias the second differential power amplifier when the detected instantaneous power level of the RF signal is lower than or equal to the first power threshold;
mapping the detected instantaneous power level of the RF signal to various levels of the second bias voltage when the detected instantaneous power level is higher than the first power threshold but lower than or equal to the second power threshold; and
determining the second bias voltage to be equal to the first bias voltage when the detected instantaneous power level of the RF signal is higher than the second power threshold.

18. The method of claim 16, further comprising:
determining a voltage differential between the supply voltage and an equivalent voltage corresponding to the detected instantaneous power level of the RF signal;
determining the second bias voltage at a first fixed level to debias the second differential power amplifier when the voltage differential is above a first bias threshold;
determining the second bias voltage at a second fixed level higher than the first fixed level to equally bias the first differential power amplifier and the second differential power amplifier when the voltage differential is below a second bias threshold lower than the first bias threshold; and
increasing the second bias voltage from the first fixed level toward the second fixed level to unequally bias the first differential power amplifier and the second differential power amplifier when the voltage differential is lower than or equal to the first bias threshold but higher than or equal to the second bias threshold.

19. The method of claim 15, further comprising presenting a termination impedance at an isolation port of the output stage circuit.

20. The method of claim 19, further comprising determining the termination impedance as one of a capacitive termination impedance, an inductive termination impedance, and a resistive termination impedance in accordance with the instantaneous power level of the RF signal.
